(19) United States
(12) Patent Application Publication
(10) Pub. No.: US 2019/0318997 A1
(43) Pub. Date: Oct. 17, 2019

(54) SEMICONDUCTOR DEVICE AND METHOD OF MANUFACTURING THE SAME

(71) Applicant: ABLIC Inc., Chiba-shi (JP)

(72) Inventors: Kohei KAWABATA, Chiba-shi (JP); Masahiro HATAKENAKA, Chiba-shi (JP)

(21) Appl. No.: 16/377,589

(22) Filed: Apr. 8, 2019

(30) Foreign Application Priority Data
Apr. 16, 2018 (JP) 2018-078516

(51) Int. Cl. H01L 23/00; H01L 29/06; H01L 23/58; H01L 23/552; H01L 23/528; H01L 23/522; H01L 23/532; H01L 29/78; H01L 29/66; H01L 21/768; H01L 21/027; H01L 21/3213

(52) U.S. Cl. CPC H01L 23/573; H01L 29/0653; H01L 23/585; H01L 23/552; H01L 23/528; H01L 23/5226; H01L 21/76802; H01L 29/78; H01L 29/66477; H01L 21/76843; H01L 21/76877; H01L 21/0273; H01L 21/32139; H01L 23/53257

(57) ABSTRACT

Provided is a semiconductor device capable of shielding X-rays irradiated from a side surface side of a semiconductor substrate and a method of manufacturing the same. The semiconductor device includes: gate insulating film; a gate electrode; a source/drain region; an element isolation region; a guard ring surrounding the element isolation region; an interlayer insulating film; a contact trench in the interlayer insulating film; a barrier metal film for shielding X-rays covering inner side surfaces and a bottom surface of the contact trench; and a metal film connected to the guard ring.

### RELATED APPLICATIONS

This application claims priority under 35 U.S.C. § 119 to Japanese Patent Application No. 2018-078516 filed on Apr. 16, 2018, the entire content of which is hereby incorporated by reference.

### BACKGROUND OF THE INVENTION

### 1. Field of the Invention

The present invention relates to a semiconductor device and a method of manufacturing the same.

### 2. Description of the Related Art

In an inspection step for a semiconductor device, irradiation of X-ray has been widely used as a method of non-destructive inspection for a disconnection inspection of bonding wires that connect lead frames to a semiconductor chip inside the semiconductor device, particularly inside a package, for a void inspection inside the resin package, and for an assembling condition inspection of the semiconductor device on a circuit board.

However, it has been known that irradiation of a large amount of X-rays on a gate insulating film formed on a semiconductor substrate in the semiconductor device permanently changes electric characteristics of the semiconductor device.

As measures against the permanent change, in Japanese Patent Laid-open No. H07-169804, an additional metal layer is formed on the top protective layer of the semiconductor device to be used as an X-ray shielding film.

However, in recent years, there has been often used an inspection equipment which irradiates X-rays from a direction parallel to a semiconductor substrate. By the structure of Japanese Patent Application Laid-open No. H07-169804, it is difficult to shield such X-rays from the direction parallel to a semiconductor substrate.

It is therefore an object of the present invention to provide a semiconductor device capable of shielding X-rays to reduce irradiation of the X-rays on a gate insulating film in X-ray inspection even in case the X-rays are irradiated from a direction parallel to a semiconductor substrate, that is, from a side surface side of the semiconductor device, and a method of manufacturing the same.

### SUMMARY OF THE INVENTION

A semiconductor device according to one embodiment of the present invention includes: gate insulating film formed on a semiconductor substrate; a gate electrode formed on the gate insulating film; source/drain regions formed in the semiconductor substrate and adjacent to the gate electrode; an element isolation region formed to surround the gate electrode and the source/drain regions; a guard ring formed in the semiconductor substrate to surround the element isolation region; a first interlayer insulating film formed to cover the gate electrode, the source/drain regions, the element isolation region, and the guard ring; a contact trench having a linear shape, and formed in the first interlayer insulating film to surround the element isolation region and to expose a surface of the guard ring; a first barrier metal film for shielding X-rays formed to cover inner side surfaces and a bottom surface of the contact trench; and a first metal film electrically connected to the guard ring, and having a first plug portion embedded in the contact trench through intermediation of the first barrier metal film, and a first wiring portion connected to the first plug portion and formed above the interlayer insulating film.

A method of manufacturing a semiconductor device according to another embodiment of the present invention includes: forming a gate insulating film on a semiconductor substrate; forming a gate electrode on the gate insulating film; forming source/drain regions in the semiconductor substrate and adjacent to the gate electrode; forming an element isolation region to surround a region in which the gate electrode and the source/drain regions are formed; forming a guard ring in the semiconductor substrate to surround the element isolation region; forming a first interlayer insulating film to cover the gate electrode, the source/drain regions, the element isolation region, and the guard ring; forming a contact trench having a linear shape in the first interlayer insulating film to surround the element isolation region and to expose a surface of the guard ring; forming a first barrier metal film for shielding X-rays to cover inner side surfaces and a bottom surface of the contact trench; and forming a first metal film electrically connected to the guard ring, and having a first plug portion embedded in the contact trench through intermediation of the barrier metal film, and a first wiring portion connected to the first plug portion and formed above the interlayer insulating film.

According to the present invention, since the linear contact trench is formed in the interlayer insulating film in order to form the metal film electrically connected to the guard ring formed in the semiconductor substrate, and since the barrier metal film for shielding X-rays is formed to cover the inner surfaces of the contact trench, irradiation of X-rays on a gate insulating film is reduced, in X-ray inspection, in case X-rays are irradiated from a side surface side of the semiconductor substrate.

### BRIEF DESCRIPTION OF THE DRAWINGS

FIG. 1 is a plan view for illustrating a structure of a semiconductor device according to an embodiment of the present invention.

FIG. 2 is a sectional view for illustrating the structure of the semiconductor device according to the embodiment of the present invention.

FIG. 3 is a sectional view taken along a process for illustrating a method of manufacturing the semiconductor device illustrated in FIG. 1 and FIG. 2.

FIG. 4 is a sectional view taken along the process for illustrating the method of manufacturing the semiconductor device illustrated in FIG. 1 and FIG. 2.

FIG. 5 is a sectional view taken along the process for illustrating the method of manufacturing the semiconductor device illustrated in FIG. 1 and FIG. 2.

FIG. 6 is a sectional view taken along the process for illustrating the method of manufacturing the semiconductor device illustrated in FIG. 1 and FIG. 2.

FIG. 7 is a sectional view taken along the process for illustrating the method of manufacturing the semiconductor device illustrated in FIG. 1 and FIG. 2.

FIG. 8 is a sectional view taken along the process for illustrating the method of manufacturing the semiconductor device illustrated in FIG. 1 and FIG. 2.

FIG. 9 is a sectional view taken along the process for illustrating the method of manufacturing the semiconductor device illustrated in FIG. 1 and FIG. 2.

FIG. 10 is a sectional view for illustrating a structure of a semiconductor device according to a first modification example of the embodiment of the present invention.

FIG. 11 is a sectional view taken along a process for illustrating a method of manufacturing the semiconductor device illustrated in FIG. 10.

FIG. 12 is a sectional view taken along the process for illustrating the method of manufacturing the semiconductor device illustrated in FIG. 10.

FIG. 13 is a sectional view for taken along the process illustrating the method of manufacturing the semiconductor device illustrated in FIG. 10.

FIG. 14 is a sectional view for illustrating a structure of a semiconductor device according to a second modification example of the embodiment of the present invention.

FIG. 15 is a sectional view taken along a process for illustrating a method of manufacturing the semiconductor device illustrated in FIG. 14.

FIG. 16 is a sectional view taken along the process for illustrating the method of manufacturing the semiconductor device illustrated in FIG. 14.

FIG. 17 is a sectional view taken along the process for illustrating the method of manufacturing the semiconductor device illustrated in FIG. 14.

FIG. 18 is a sectional view taken along the process for illustrating the method of manufacturing the semiconductor device illustrated in FIG. 14.

FIG. 19 is a sectional view taken along the process for illustrating the method of manufacturing the semiconductor device illustrated in FIG. 14.

### DETAILED DESCRIPTION OF THE PREFERRED EMBODIMENTS

Now, embodiments of the present invention are described in detail with reference to the drawings.

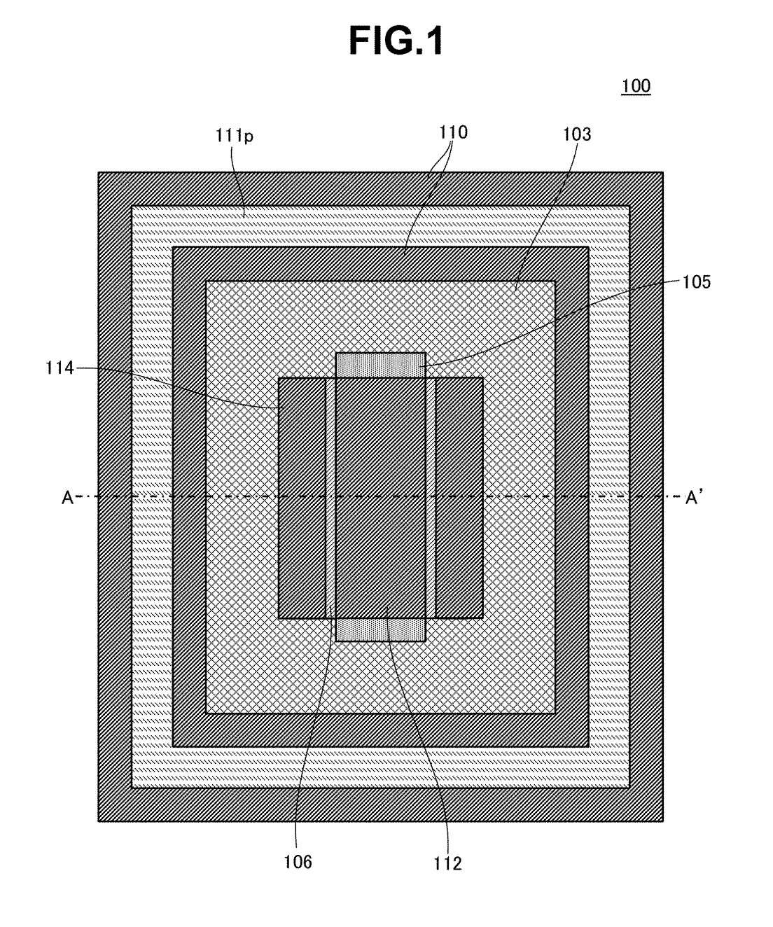

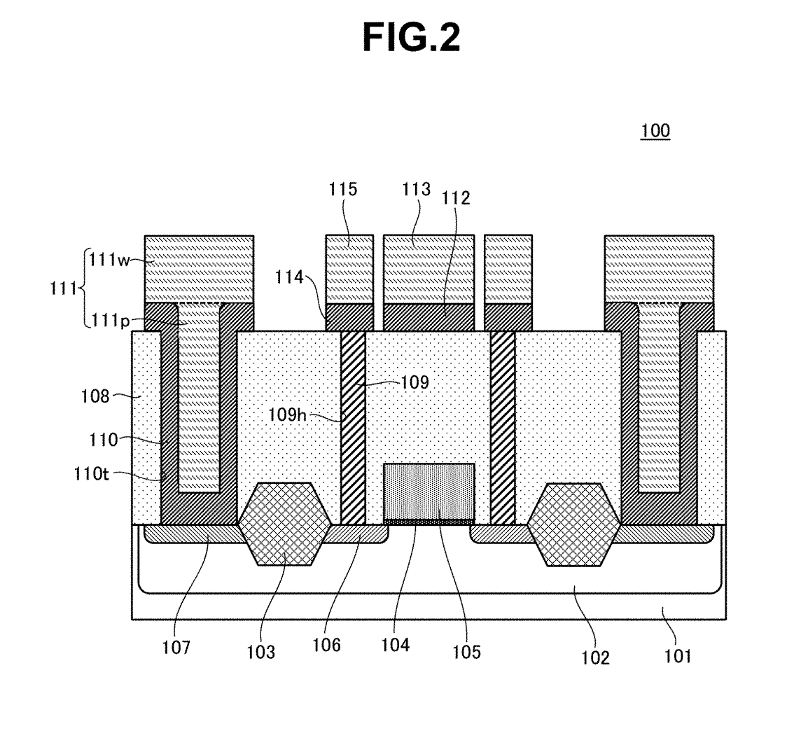

FIG. 1 is a schematic plan view for illustrating the structure of a semiconductor device 100 according to an embodiment of the present invention, and FIG. 2 is a sectional view taken along the line A-A′ of FIG. 1.

As illustrated in FIG. 1 and FIG. 2, the semiconductor device 100 according to the embodiment includes: a semiconductor substrate 101, a P-type well 102 formed in the semiconductor substrate 101; an element isolation region 103 formed so as to surround an element formation region of the semiconductor substrate 101; a gate insulating film 104 formed on the semiconductor substrate 101 in the element formation region; a gate electrode 105 formed on the gate insulating film 104; source/drain regions 106 formed of an N-type diffusion layer, and formed in the semiconductor substrate 101 so as to be adjacent to the gate electrode 105; a guard ring 107 formed of a P-type diffusion layer, and formed in the semiconductor substrate 101 so as to surround the element isolation region 103; an interlayer insulating film 108 formed so as to cover the gate electrode 105, the source/drain regions 106, the element isolation region 103, and the guard ring 107; a linear contact trench 110t formed in the interlayer insulating film 108 so as to surround the element isolation region 103 and to expose a surface of the guard ring 107; a barrier metal film 110 for shielding X-rays formed so as to cover inner side surfaces and a bottom surface of the contact trench 110t; and a metal film 111 electrically connected to the guard ring 107, the metal film 111 including a plug portion 111p which is embedded in the contact trench 110t through intermediation of the barrier metal film 110, and a wiring portion 111w which is connected to the plug portion 111p and is formed above the interlayer insulating film 108. In this case, the guard ring 107 is formed to supply an electric potential to the well 102.

In the interlayer insulating film 108, contact holes 109h by which surfaces of the source/drain regions 106 are exposed are formed, and contact plugs 109 are embedded in the contact holes 109h.

The semiconductor device 100 further includes: a barrier metal film 112 for shielding X-rays formed on the interlayer insulating film 108 in a region overlapping with at least the gate insulating film 104 in plan view; barrier metal films 114 formed on the contact plugs 109; and a wiring portion 113 and wiring portions 115 which are formed on the barrier metal film 112 and the barrier metal films 114, respectively, and which form a portion of the same metal wiring layer as the wiring portion 111w. All the barrier metal films 110, 112, and 114 are made of the same material capable of shielding X-rays, and are made of a film containing titanium tungsten in the embodiment.

According to the semiconductor device 100 constituted as described above, the portion for electrically connecting the guard ring 107 to the wiring portion 111w includes the structure in which the linear contact trench 110t is formed in the interlayer insulating film 108 in which the barrier metal film 110 for shielding X-rays is formed so as to cover the inner side surfaces of the contact trench 110t, and in which the plug portion 111p is formed through intermediation of the barrier metal film 110. Accordingly, in X-ray inspection, the X-rays from a direction parallel to the semiconductor substrate 101, that is, from a side surface direction thereof can be shielded, and irradiation of the X-rays on the gate insulating film 104 can be reduced.

Further, in the embodiment, since the barrier metal film 112 for shielding X-rays is formed on the interlayer insulating film 108 in the region overlapping with the gate insulating film 104 in plan view, irradiation of the X-rays on the gate insulating film 104 can be reduced even in case an inspection equipment which irradiates X-rays from an upper surface direction of the semiconductor substrate 101 is used.

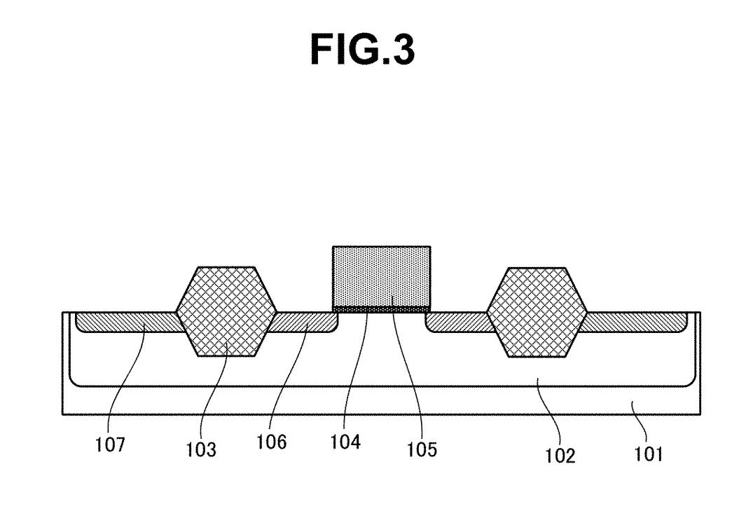

Next, a method of manufacturing the semiconductor device 100 illustrated in FIG. 1 and FIG. 2 is described with reference to sectional views taken along a process and illustrated in FIG. 3 to FIG. 9.

First, as illustrated in FIG. 3, the element isolation region 103 is formed by LOCOS method, for example, in the semiconductor substrate 101 so as to surround the element formation region. Next, P-type impurities are introduced into the semiconductor substrate 101 to form the P-type well 102. After an insulating film and a polysilicon film are sequentially formed on the semiconductor substrate 101, the laminated film formed of the insulating film and the polysilicon film is patterned by photolithography and etching, to thereby form the gate insulating film 104 and the gate electrode 105 on the semiconductor substrate 101 in the element formation region. Next, N-type impurities are ion-implanted with the use of the gate electrode 105 as a mask to form the source/drain regions 106 in the semiconductor substrate 101. After that, P-type impurities are ion-implanted with the use of a resist pattern (not shown) covering the element formation region surrounded by the element isolation region 103 as a mask to form the P-type guard ring 107 in the semiconductor substrate 101.

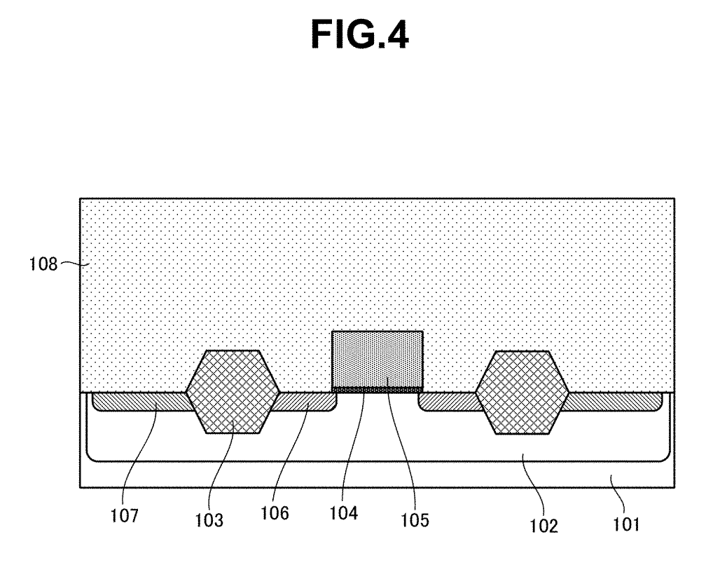

Next, as illustrated in FIG. 4, the interlayer insulating film 108 is formed on an entire surface so as to cover the gate electrode 105, the source/drain regions 106, the element isolation region 103, and the guard ring 107.

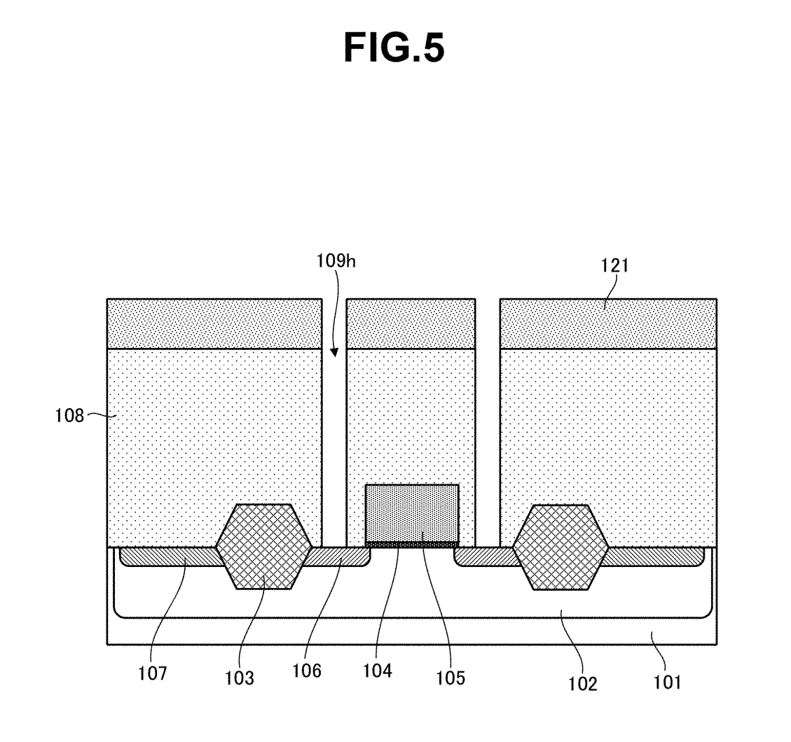

Next, as illustrated in FIG. 5, a resist pattern 121 having openings in regions overlapping with the source/drain regions 106 in plan view is formed on the interlayer insulating film 108, and the interlayer insulating film 108 is etched with the use of the resist pattern 121 as a mask to form the contact holes 109h at which the surfaces of the source/drain regions 106 are exposed.

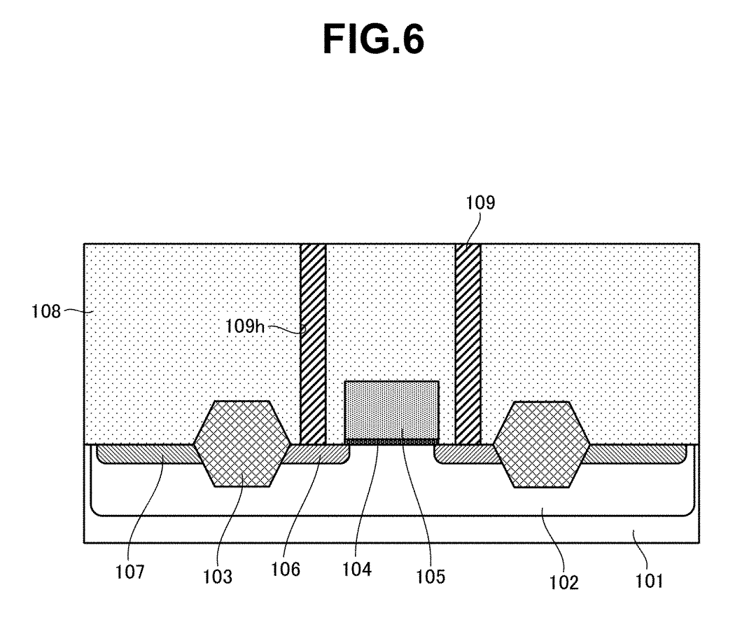

After the resist pattern 121 is removed, a conductive film is formed in the contact holes 109h and on the interlayer insulating film 108, and the conductive film on the interlayer insulating film 108 is removed by etch back to leave the conductive film only in the contact holes 109h. As a result, as illustrated in FIG. 6, the contact plugs 109 embedded in the contact holes 109h are formed.

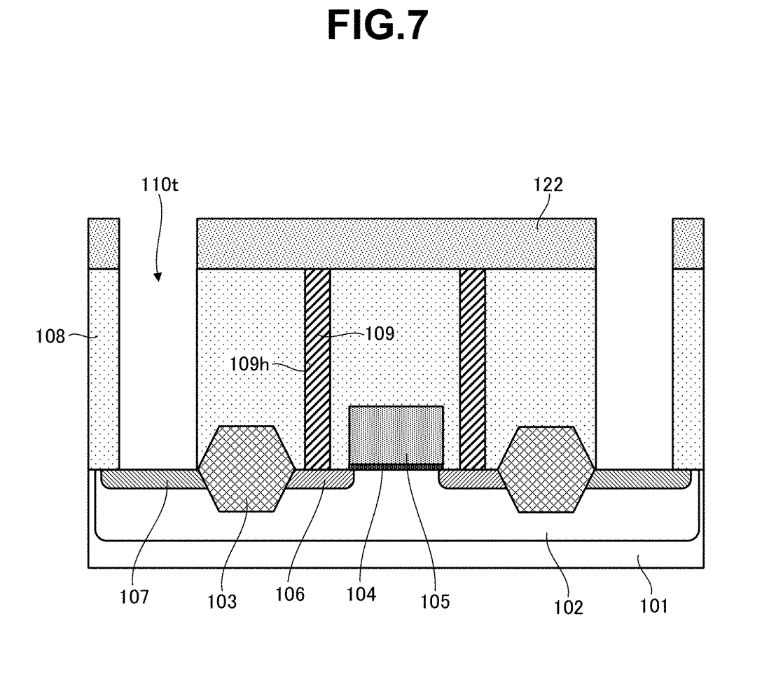

Next, as illustrated in FIG. 7, a resist pattern 122 having openings in regions overlapping with the guard ring 107 in plan view is formed, and the interlayer insulating film 108 is etched with the use of the resist pattern 122 as a mask to form the contact trench 110t at which the surface of the guard ring 107 is exposed.

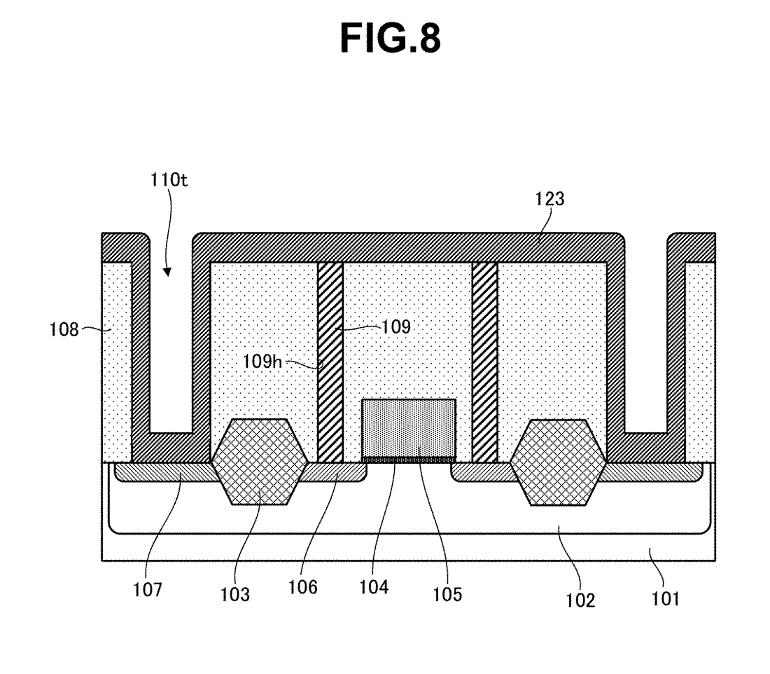

After the resist pattern 122 is removed, as illustrated in FIG. 8, a barrier metal layer 123 containing titanium tungsten which is a material capable of shielding X-rays is formed so as to cover the inner side surfaces and the bottom surface of the contact trench 110t and an upper surface of the interlayer insulating film 108.

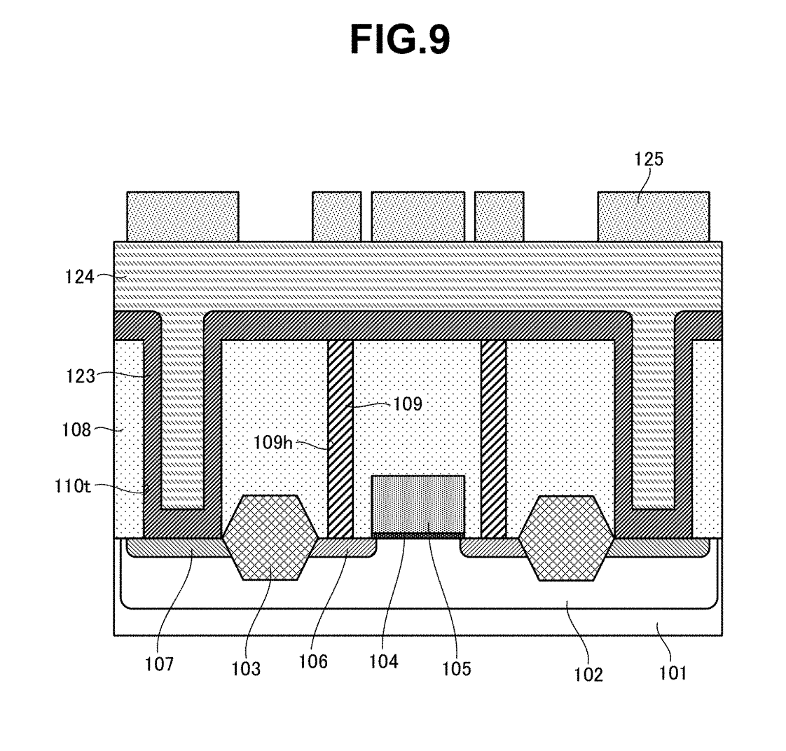

Then, as illustrated in FIG. 9, a metal layer 124 is formed in the contact trench 110t and on the interlayer insulating film 108 through intermediation of the barrier metal layer 123. Next, on the metal layer 124, a resist pattern 125 is formed to selectively cover regions overlapping respectively with the contact trench 110t, the contact holes 109h, and the gate insulating film 104 in plan view.

After that, the metal layer 124 and the barrier metal layer 123 are patterned by etching with the use of the resist pattern 125 as a mask to simultaneously form the barrier metal films 110, 112, and 114, the metal film 111 including the plug portions 111p and the wiring portions 111w, the wiring portion 113, and the wiring portions 115 illustrated in FIG. 2.

In the manner described above, the semiconductor device 100 illustrated in FIG. 1 and FIG. 2 is formed.

Thus, according to the method of manufacturing the semiconductor device 100 of the embodiment, there is an advantage in that the barrier metal film 110 for shielding X-rays from the side surface direction of the semiconductor substrate 101 and the barrier metal film 112 for shielding X-rays from the upper surface direction of the semiconductor substrate 101 can be simultaneously formed in the same step.

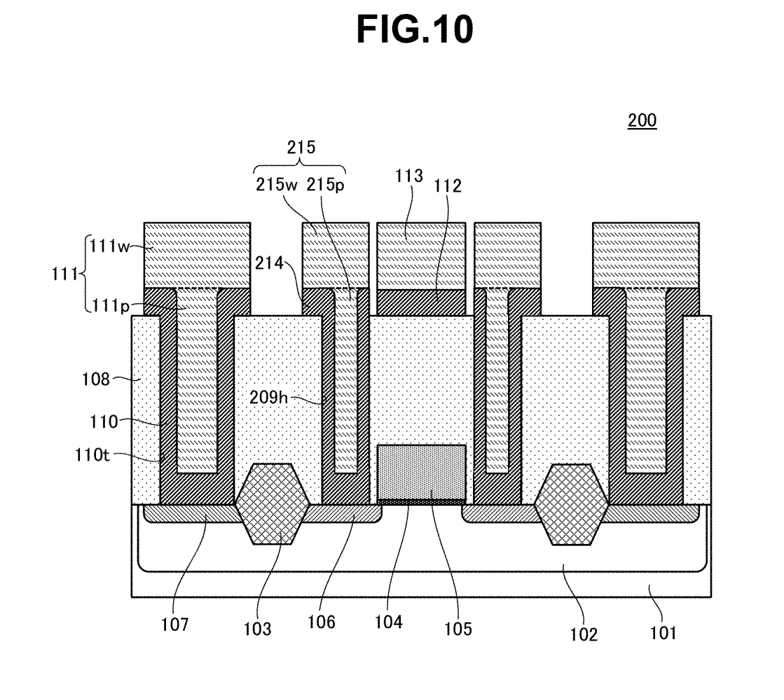

FIG. 10 is a sectional view for illustrating the structure of a semiconductor device 200 according to the first modification example of the embodiment of the present invention. The same components as those of the semiconductor device 100 illustrated in FIG. 1 and FIG. 2 are denoted by the same reference symbols, and redundant description is omitted as appropriate.

In the semiconductor device 200 according to the first modification example, an opening area of contact holes 209h at which the source/drain regions 106 are exposed in the interlayer insulating film 108 is larger than that of the contact holes 109h in the semiconductor device 100 illustrated in FIG. 2, and barrier metal films 214 for shielding X-rays are formed so as to cover inner side surfaces and the bottom surfaces of the contact holes 209h. In the contact holes 209h, plug portions 215p are embedded through intermediation of the barrier metal films 214. Further, wiring portions 215w connected to the plug portions 215p are formed above the interlayer insulating film 108, and metal films 215 are formed to include the plug portions 215p and the wiring portions 215w. The wiring portions 215w form a portion of the same metal wiring layer as the wiring portions 111w and the wiring portion 113.

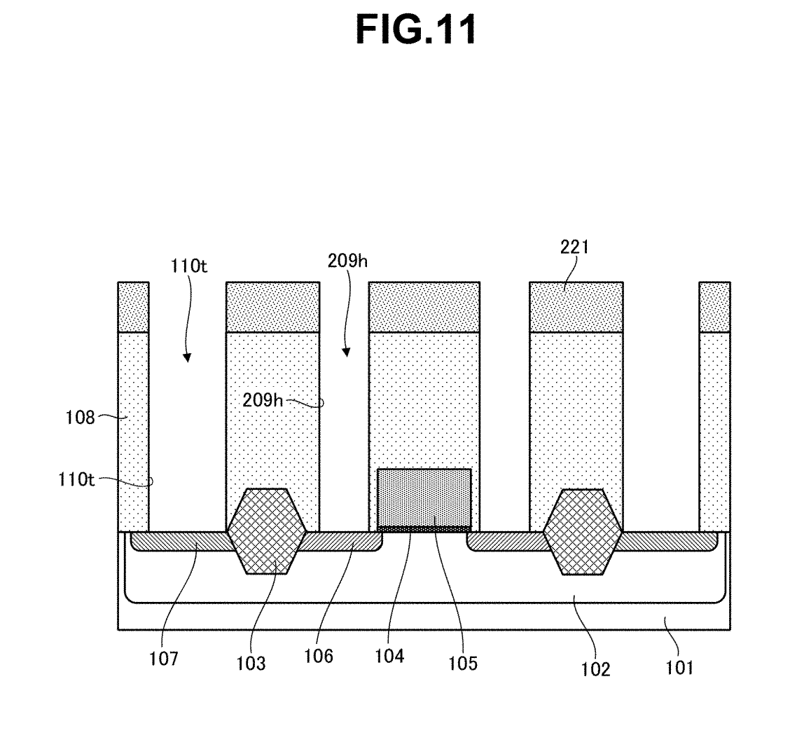

Next, a method of manufacturing the semiconductor device 200 illustrated in FIG. 10 is described with reference to sectional views taken along a process and illustrated in FIG. 11 to FIG. 13.

A method of manufacturing the semiconductor device 200 is the same as the method of manufacturing the semiconductor device 100 up to the forming of the interlayer insulating film 108 illustrated in FIG. 4.

After the process illustrated in FIG. 4, as illustrated in FIG. 11, a resist pattern 221 having openings in regions overlapping with the source/drain regions 106 and the guard ring 107 in plan view is formed on the interlayer insulating film 108, and the interlayer insulating film 108 is etched with the use of the resist pattern 221 as a mask to form contact holes 209h and the contact trench 110t at which the surfaces of the source/drain regions 106 and the surface of the guard ring 107 are exposed, respectively.

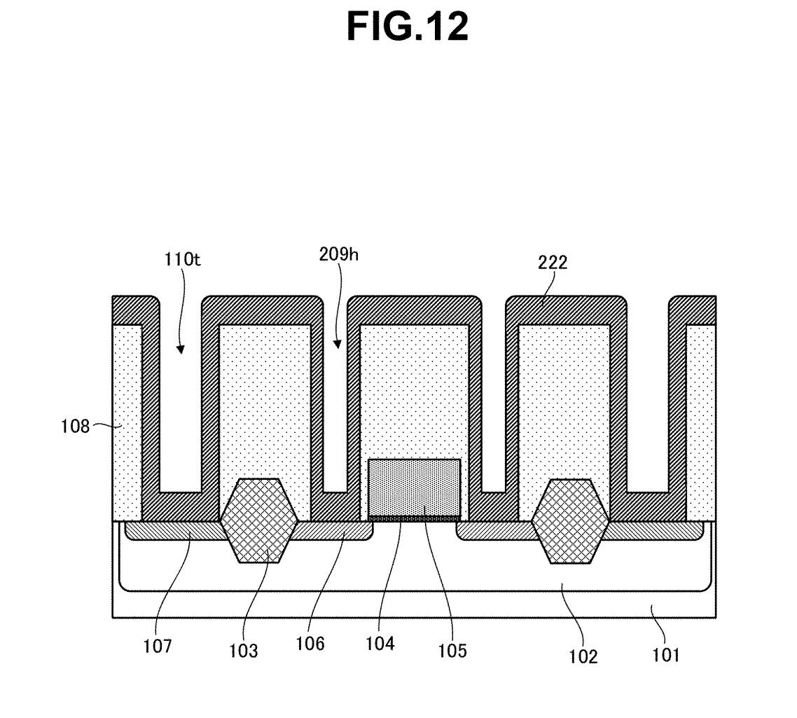

After the resist pattern 221 is removed, as illustrated in FIG. 12, a barrier metal layer 222 containing titanium tungsten which is a material capable of shielding X-rays is formed on the inner side surfaces and the bottom surface of each of the contact holes 209h and the contact trench 110t and on the interlayer insulating film 108.

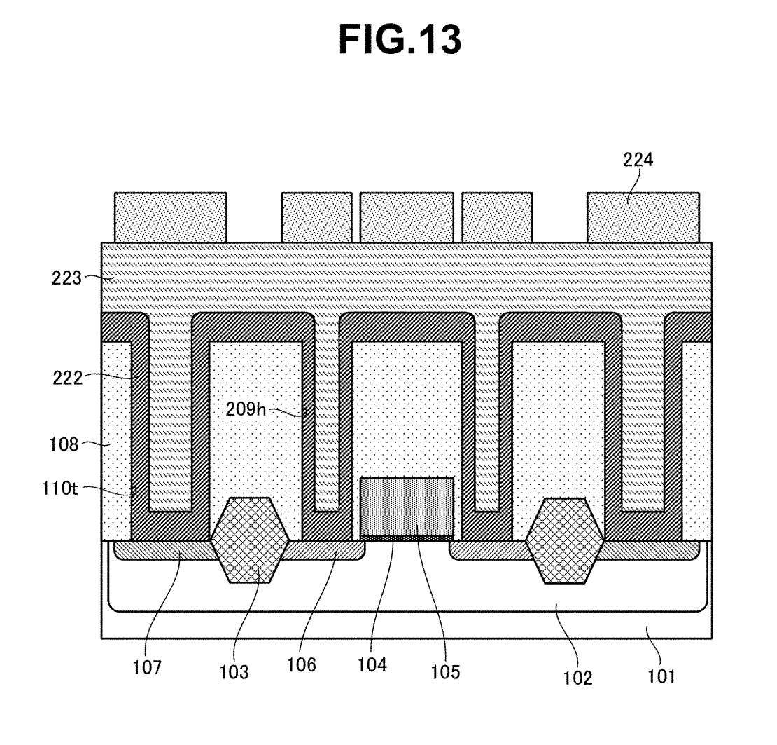

Then, as illustrated in FIG. 13, a metal layer 223 is formed in the contact holes 209h, in the contact trench 110t, and on the interlayer insulating film 108 through intermediation of the barrier metal layer 222. Next, on the metal layer 223, a resist pattern 224 is formed to selectively cover regions overlapping respectively with the contact trench 110t, the contact holes 209h, and the gate insulating film 104 in plan view. After that, the metal layer 223 and the barrier metal layer 222 are patterned by etching with the use of the resist pattern 224 as a mask to simultaneously form the barrier metal films 110, 112, and 214, the metal film 111 including the plug portions 111p and the wiring portions 111w, the wiring portion 113, and the metal films 215 including the plug portions 215p and the wiring portions 215w illustrated in FIG. 10.

In the manner described above, the semiconductor device 200 illustrated in FIG. 10 is formed.

According to the first modification example, the barrier metal films 214 in the contact holes 209h and the barrier metal film 110 in the contact trench 110t can be formed in the same process in case a barrier metal film is needed in the contact hole. That is, the barrier metal film 110 for shielding X-rays can be formed in the contact trench 110t without adding a dedicated process for forming the barrier metal film 110 in the contact trench 110t.

In the first modification example, in case one of the source/drain regions 106 formed on both sides of the gate electrode 105 is allowed to electrically connect to the wiring portion 113, in the forming of the resist pattern 224 illustrated in FIG. 13, for example, it is preferred that the resist pattern 224 positioned above the gate insulating film 104 and the resist pattern 224 positioned above one of the contact holes 209h is integrally formed without being separated, and that the metal layer 223 and the barrier metal layer 222 are patterned with the use of the integrally formed resist pattern as a mask so that the barrier metal film 112 and one of the barrier metal films 214, and the wiring portion 113 and one of the wiring portions 215w are integrally formed, respectively.

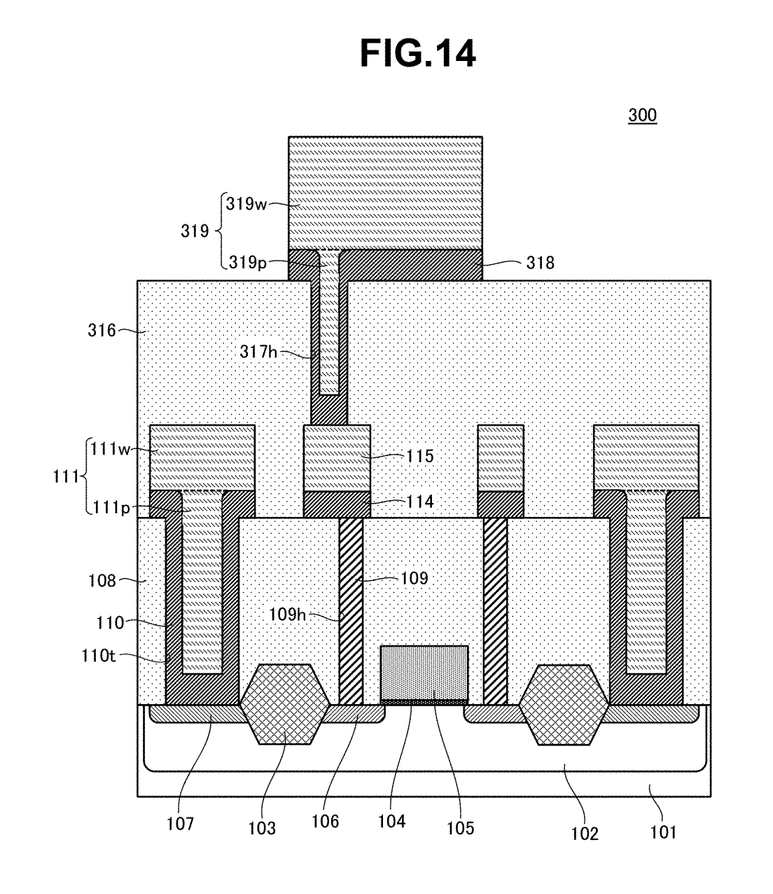

FIG. 14 is a sectional view for illustrating the structure of a semiconductor device 300 according to the second modification example of the embodiment of the present invention. In the second modification example, the same components as those of the semiconductor device 100 illustrated in FIG. 1 and FIG. 2 are also denoted by the same reference symbols, and redundant description is omitted as appropriate.

The semiconductor device 300 according to the second modification example includes a barrier metal film for shielding X-rays formed in a region overlapping with at least the gate insulating film 104 in plan view on a second-layer interlayer insulating film without having the barrier metal film 112 and the wiring portion 113 in the semiconductor device 100.

Specifically, the semiconductor device 300 has the structure of the semiconductor device 100 without including the barrier metal film 112 and the wiring portion 113, and further includes: a second-layer interlayer insulating film 316 formed to cover the wiring portions 111w and the wiring portions 115 forming the first-layer metal wiring layer; a contact hole 317h at which a surface of the wiring portion 115 formed in the interlayer insulating film 316 is exposed; a barrier metal film 318 for shielding X-rays which covers inner side surfaces and a bottom surface of the contact hole 317h, and which is formed in a region overlapping with at least the gate insulating film 104 in plan view on the interlayer insulating film 316; and a metal film 319 electrically connected to the wiring portion 115, the metal film 319 including a plug portion 319p which is embedded in the contact hole 317h through intermediation of the barrier metal film 318, and a wiring portion 319w which is connected to the plug portion 319p and is formed on the interlayer insulating film 316 through intermediation of the barrier metal film 318.

According to the second modification example, since the barrier metal film 318 capable of shielding X-rays is formed on the interlayer insulating film 316 in the region overlapping with at least the gate insulating film 104 in plan view, it is possible to reduce X-rays from irradiating the gate insulating film 104 even in case the X-rays are irradiated from the upper surface direction of the semiconductor substrate 101, even if miniaturization progresses in the semiconductor device 100 illustrated in FIG. 2 and thus wiring intervals between the wiring portion 113 and the barrier metal film 112 and between the wiring portions 115 and the barrier metal films 114 are hard to be maintained so that the barrier metal film 112 for shielding X-rays cannot be formed on the interlayer insulating film 108 in the region overlapping with the gate insulating film 104 in plan view.

In the semiconductor device 300 of the second modification example, though the barrier metal film 318 and the metal film 319 are electrically connected to the wiring portion 115, it is only required to form the barrier metal film 318 (and the metal film 319) in the region overlapping with the gate insulating film 104 in plan view above the interlayer insulating film 108. The wiring portion of the first-layer metal wiring layer which electrically connects the barrier metal film 318 and the metal film 319 is not limited to the wiring portion 115.

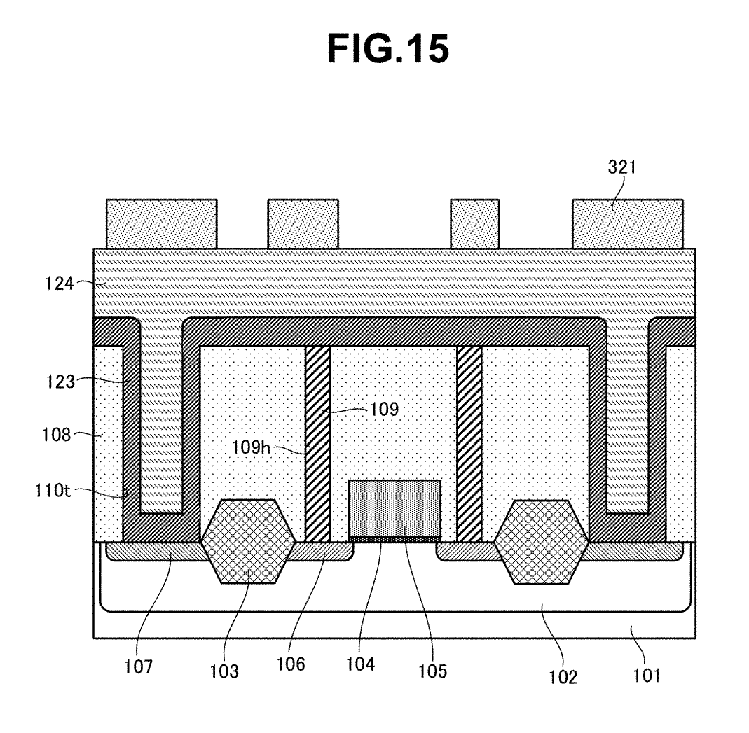

Next, a method of manufacturing the semiconductor device 300 illustrated in FIG. 14 is described with reference to sectional views taken along a process illustrated in FIG. 15 to FIG. 19.

The method of manufacturing the semiconductor device 300 is the same as the method of manufacturing the semiconductor device 100 up to the formation of the barrier metal layer 123 illustrated in FIG. 8.

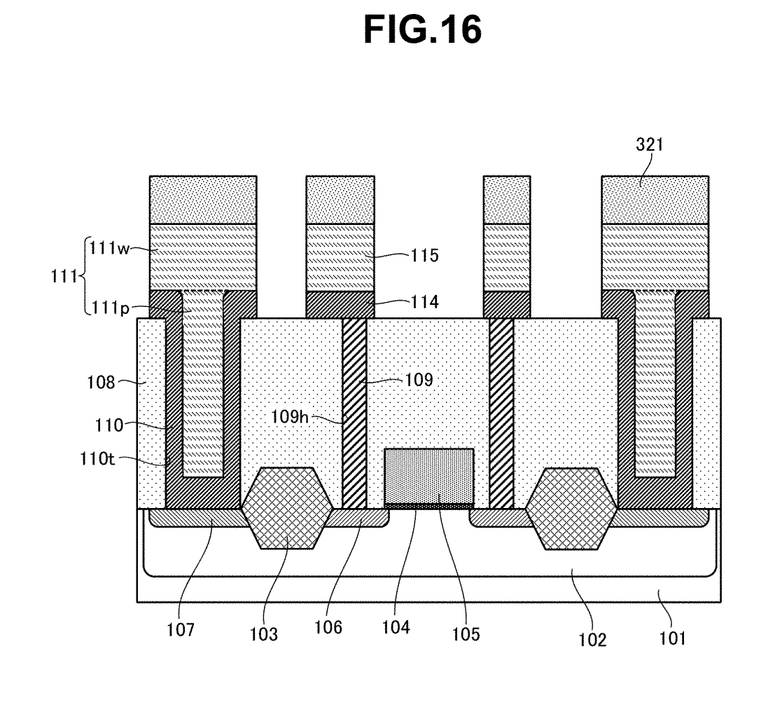

After the process of FIG. 8, as illustrated in FIG. 15, a metal layer 124 is formed in the contact trench 110t and on the interlayer insulating film 108 through intermediation of the barrier metal layer 123. Next, a resist pattern 321 is formed to selectively cover regions overlapping on the metal layer 124 respectively with the contact trench 110t and the contact plugs 109 in plan view. After that, the metal layer 124 and the barrier metal layer 123 are patterned by etching with the use of the resist pattern 321 as a mask to simultaneously form the barrier metal films 110 and 114, the metal film 111 including the plug portions 111p and the wiring portions 111w, and the wiring portions 115 illustrated in FIG. 16.

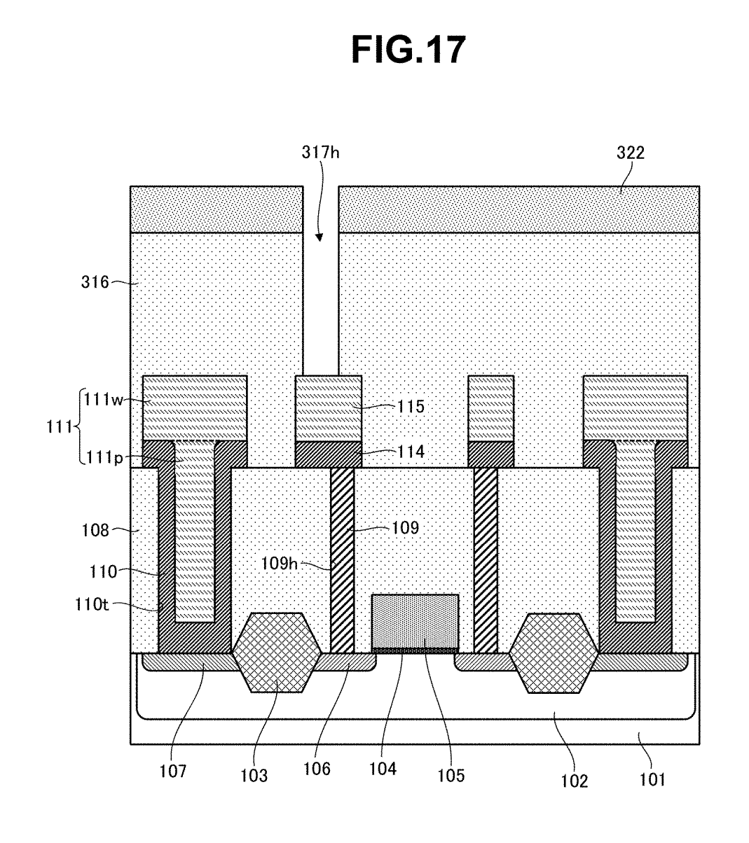

After the resist pattern 321 is removed, as illustrated in FIG. 17, the interlayer insulating film 316 is formed on the interlayer insulating film 108 so as to cover the wiring portion 111w and the wiring portions 115. Next, a resist pattern 322 having openings in regions overlapping with the wiring portions 115 in plan view is formed on the interlayer insulating film 316, and the interlayer insulating film 316 is etched with the use of the resist pattern 322 as a mask to form the contact holes 317h at which the surfaces of the wiring portions 115 are exposed.

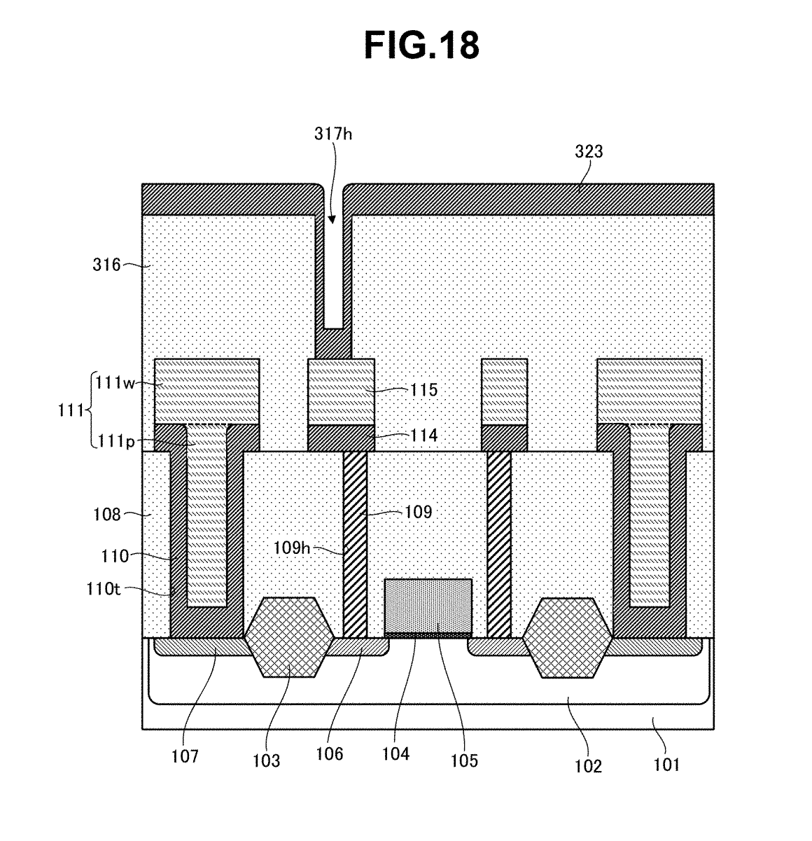

After the resist pattern 322 is removed, as illustrated in FIG. 18, a barrier metal layer 323 containing titanium tungsten which is a material capable of shielding X-rays is formed to cover the inner side surfaces and the bottom surface of the contact hole 317h and an upper surface of the interlayer insulating film 316.

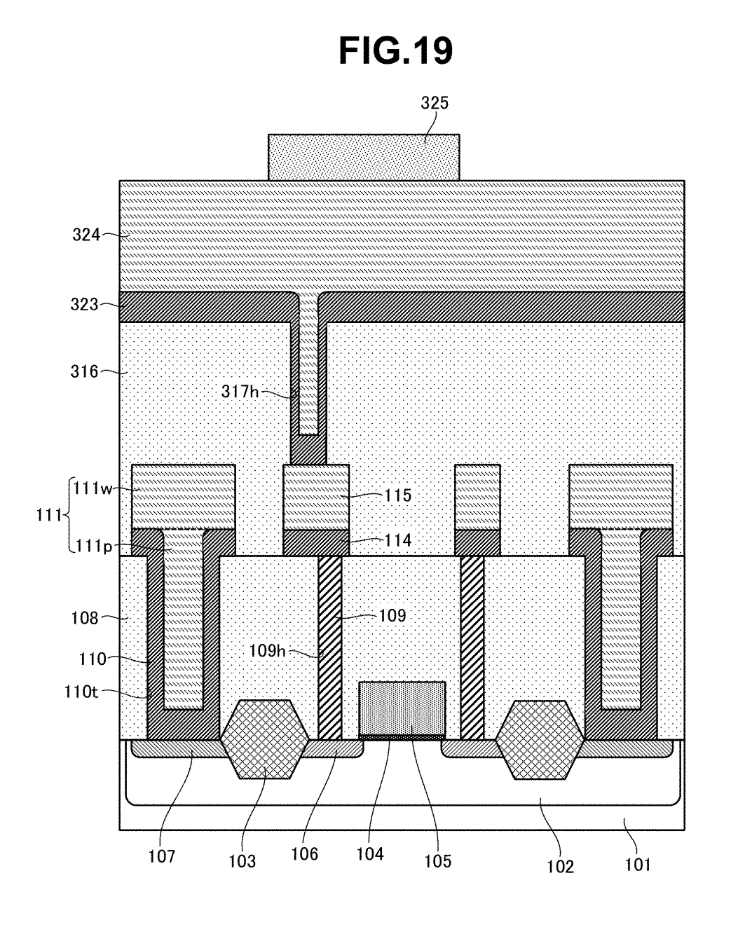

After that, as illustrated in FIG. 19, a metal layer 324 is formed in the contact hole 317h and on the interlayer insulating film 316 through intermediation of the barrier metal layer 323. Next, a resist pattern 325 is formed to selectively cover region overlapping with at least the gate insulating film 104 in plan view on the metal layer 324.

Next, the metal layer 324 and the barrier metal layer 323 are patterned by etching with the use of the resist pattern 325 as a mask to simultaneously form the barrier metal film 318 and the metal film 319 including the plug portion 319p and the wiring portion 319w illustrated in FIG. 14.

In the manner described above, the semiconductor device 300 illustrated in FIG. 14 is formed.

Though the embodiments of the present invention have been described above, it is apparent that the present invention is not limited to the above embodiments and it is to be understood that various modifications and changes can be made thereto without departing from the gist and scope of the present invention.

For example, in the embodiments described above, description has been given of examples in which the source/drain regions 106 have an N-type conductivity and the well 102 and the guard ring 107 have a P-type conductivity, but the type of conductivity may be reversed.

What is claimed is:

1. A semiconductor device, comprising:
a gate insulating film formed on a semiconductor substrate;
a gate electrode formed on the gate insulating film;
source/drain regions formed in the semiconductor substrate to be adjacent to the gate electrode;
an element isolation region formed to surround the gate electrode and the source/drain regions;
a guard ring formed in the semiconductor substrate to surround the element isolation region;
a first interlayer insulating film formed to cover the gate electrode, the source/drain regions, the element isolation region, and the guard ring;
a contact trench having a linear shape, and formed in the first interlayer insulating film to surround the element isolation region and to expose a surface of the guard ring;
a first barrier metal film for shielding X-rays formed to cover inner side surfaces and a bottom surface of the contact trench; and
a first metal film electrically connected to the guard ring, and having a first plug portion embedded in the contact trench through intermediation of the first barrier metal film, and a first wiring portion connected to the first plug portion and formed above the first interlayer insulating film.

2. The semiconductor device according to claim 1, further comprising:
a second barrier metal film for shielding X-rays formed on the first interlayer insulating film in a region overlapping with at least the gate insulating film in plan view; and
a second wiring portion formed on the second barrier metal film, and forming a portion of the same metal wiring layer as the first wiring portion.

3. The semiconductor device according to claim 2, wherein the first barrier metal film and the second barrier metal film are made of the same material.

4. The semiconductor device according to claim 1, further comprising:
a contact hole formed in the first interlayer insulating film to expose a surface of the source/drain regions;
a third barrier metal film made of the same material as a material of the first barrier metal film and formed to cover inner side surfaces and a bottom surface of the contact hole; and
a second metal film electrically connected to the source/drain regions and made of the same material as a material of the first metal film, the second metal film including a second plug portion embedded in the contact hole through intermediation of the third barrier metal film, and a third wiring portion connected to the second plug portion and forming a portion of the same metal wiring layer as the first metal film formed on the first interlayer insulating film.

5. The semiconductor device according to claim 1, further comprising:
a second interlayer insulating film formed on the first interlayer insulating film to cover the first wiring portion;
a second barrier metal film for shielding X-rays formed on the second interlayer insulating film in a region overlapping with at least the gate insulating film in plan view; and
a second wiring portion formed on the second barrier metal film.

6. The semiconductor device according to claim 1, wherein the first barrier metal film contains titanium tungsten.

7. A method of manufacturing a semiconductor device, comprising:
forming a gate insulating film on a semiconductor substrate;
forming a gate electrode on the gate insulating film;
forming source/drain regions in the semiconductor substrate to be adjacent to the gate electrode;
forming an element isolation region to surround a region in which the gate electrode and the source/drain regions are formed;
forming a guard ring in the semiconductor substrate to surround the element isolation region;
forming a first interlayer insulating film to cover the gate electrode, the source/drain regions, the element isolation region, and the guard ring;
forming a contact trench having a linear shape in the first interlayer insulating film to surround the element isolation region and to expose a surface of the guard ring;
forming a first barrier metal film for shielding X-rays to cover inner side surfaces and a bottom surface of the contact trench; and
forming a first metal film electrically connected to the guard ring, and having a first plug portion embedded in the contact trench through intermediation of the first barrier metal film, and a first wiring portion connected to the first plug portion and formed above the first interlayer insulating film.

8. The method of manufacturing a semiconductor device according to claim 7, wherein the forming of the first barrier metal film and the forming of the first metal film comprises:
forming a barrier metal layer for shielding X-rays on the inner surfaces and the bottom surface of the contact trench and on the first interlayer insulating film;
forming a metal layer in the contact trench and on the first interlayer insulating film through intermediation of the barrier metal layer;
forming a resist pattern selectively in a region overlapping with at least the contact trench in plan view on the metal layer; and
forming the first metal film including the first barrier metal film by etching the metal layer and the barrier metal layer to leave a part of the barrier metal layer and a part of the metal layer in the contact trench with the use of the resist pattern as a mask.

9. The method of manufacturing a semiconductor device according to claim 8, wherein the forming of the first barrier metal film and the forming of the first metal film comprise:
forming the resist pattern selectively also in a region overlapping with at least the gate insulating film in plan view on the metal layer; and
forming a second barrier metal film by etching the metal layer and the barrier metal layer to leave a part of the barrier metal layer in the region overlapping with at least the gate insulating film in plan view, and forming a second wiring portion where the metal layer remains on the second barrier metal film to form a portion of the same metal wiring layer as the first wiring portion with the use of the resist pattern as a mask.

10. The method of manufacturing a semiconductor device according to claim 8, further comprising forming a contact hole in the first interlayer insulating film to expose a surface of the source/drain regions, wherein the forming of the first barrier metal film and the forming of the first metal film comprise:
forming the barrier metal layer also on inner side surfaces and a bottom surface of the contact hole;
forming the resist pattern selectively also in a region overlapping with at least the contact hole in plan view on the metal layer; and
forming a third barrier metal film by etching the metal layer and the barrier metal layer to leave a part of the barrier metal layer in the contact hole, and forming a second metal film where the metal layer remains with the use of the resist pattern as a mask, the second metal film being electrically connected to the source/drain regions and including a second plug portion formed by the metal layer being left in the contact hole and embedded in the contact hole through intermediation of the third barrier metal film, and a third wiring portion connected to the second plug portion and which forms a portion of the same metal wiring layer as the first wiring portion formed above the first interlayer insulating film.

11. The method of manufacturing a semiconductor device according to claim 7, further comprising:
forming a second interlayer insulating film on the first interlayer insulating film to cover the first wiring portion;
forming a second barrier metal film for shielding X-rays on the second interlayer insulating film in a region overlapping with at least the gate insulating film in plan view; and
forming a second wiring portion on the second barrier metal film.

12. The method of manufacturing a semiconductor device according to claim 7, wherein the first barrier metal film contains titanium tungsten.
